(19) United States
(12) Patent Application Publication
(10) Pub. No.: US 2012/0193217 A1
(43) Pub. Date: Aug. 2, 2012

(54) SEGMENTED POST CATHODE

(76) Inventors: Brian S. Tryon, Glastonbury, CT (US); Russell A. Beers, Manchester, CT (US)

(21) Appl. No.: 13/019,325

(22) Filed: Feb. 2, 2011

(51) Int. Cl. C25B 11/00; C23C 14/34

(52) U.S. Cl. 204/192.12; 204/298.01

(57) ABSTRACT

A physical vapor deposition system includes a segmented post cathode having multiple post segments.

### BACKGROUND

The present disclosure is directed toward a physical vapor deposition (PVD) system, and particularly to a segmented post cathode for use therein.

Cathodic arc is one type of physical vapor deposition (PVD) system which vaporizes a material and deposits that material on a piece, thereby coating the piece with a thin layer of the material. PVD systems use a cathode/anode arrangement where the cathode includes an evaporation surface made from the coating material. The cathode and the anode of the PVD system are contained within a vacuum chamber. A power source is connected to the cathode and the anode with the positive connection of the power source connected to the anode and the negative connection of the power source connected to the cathode. By connecting the positive power connection to the anode and the negative power connection to the cathode, a charge disparity between the anode and the cathode is generated. The charge disparity causes an electrical arc to jump between the cathode and the anode. In standard cathodic arc systems, the arc location is random over the surface of the cathode. The arcing causes the surface of the cathode to vaporize at the point where the arc occurred. The plasma formed from the vaporized cathode material then coats the electrically biased piece(s) contained in the vacuum chamber.

In order to control the density and distribution of the coating, steered arc systems control the location of the arc on the cathode's surface by manipulating magnetic fields. The magnetic field is created using an array of magnets or electromagnets which force the arc into the desired location(s) on the source (cathode) material and further helps to keep the arc away from undesirable/shielded locations of the apparatus.

Additionally, multiple coatings of different materials can be required. Typically, in order to implement multiple-layer coatings, a first layer is applied using the method described above. After the first layer is applied, the part is removed from the PVD system, the cathode is replaced with a cathode constructed of the second coating material, and the process is repeated. Further layers beyond the second require additional cathode changes. Systems with multiple sources can produce multiple layer coatings, but suffer from potential cross-contamination, and other added complexities, such as a plurality of triggering mechanisms, a plurality of cathode shielding, and a plurality of cooling systems.

### SUMMARY

Disclosed is a segmented post cathode for a physical vapor deposition (PVD) system having multiple post segments, each of the segments is cylindrical and has an aligned central axis. Each of the segments abuts at least one other segment.

Also disclosed is a PVD system having a vacuum chamber with an inner surface and a cathode within the vacuum chamber. The cathode has multiple hollow cylindrical cathode segments, and a magnet suspended in a shared void within the cathode segments. The magnet is connected to a shaft such that the magnet can be moved axially between the segments.

### BRIEF DESCRIPTION OF THE DRAWINGS

The disclosure can be further understood by reference to the following detailed description when considered in connection with the accompanying drawings wherein:

FIG. 1 illustrates an example steered arc post cathode system having multiple post cathode segments.

FIG. 2 illustrates a first example post segment.

FIG. 3 illustrates a second example post segment.

FIG. 4 illustrates a third example post segment.

### DETAILED DESCRIPTION

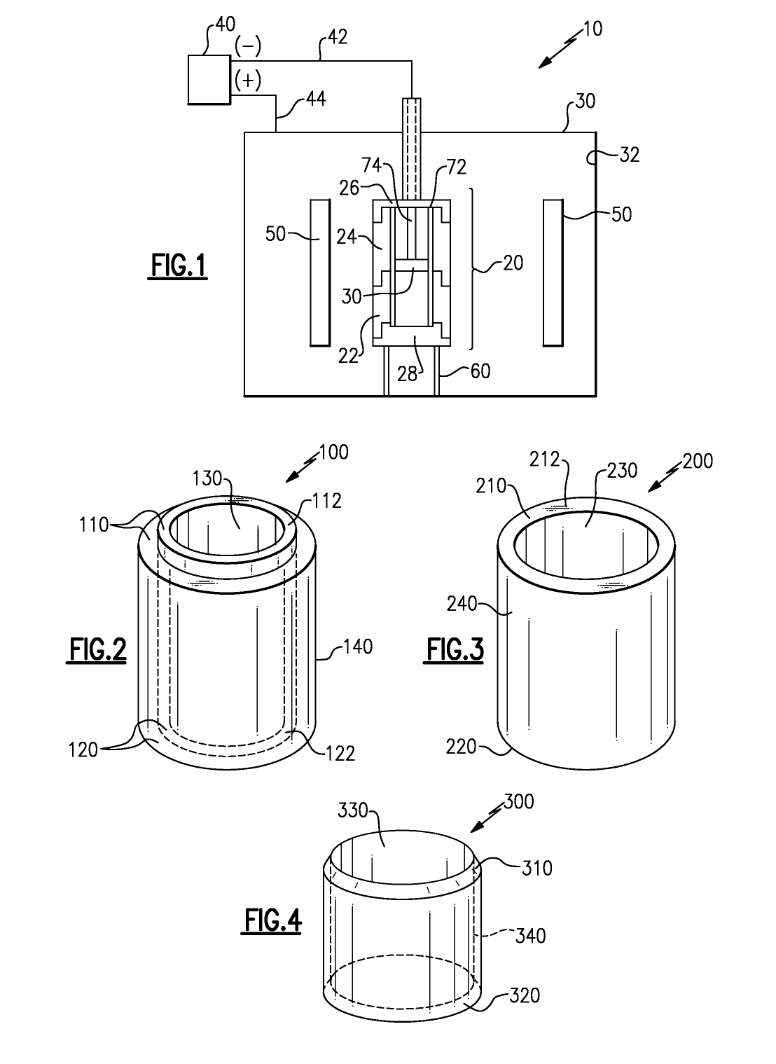

FIG. 1 illustrates an example steered arc physical vapor deposition (PVD) system 10. The PVD system 10 includes a vacuum chamber 30 surrounding a cylindrical post cathode 20. The vacuum chamber 30 includes an inner surface 32 that further doubles as an anode. Alternately, an independent anode (not shown) can be connected within the vacuum chamber 30 to the same effect. Each of the anode 32 and the cylindrical post cathode 20 are connected to a power source 40. The power source 40 provides a negative charge 42 to the cylindrical cathode 20 and a positive charge 44 to the anode 32 during operation, thereby enabling cathodic arcing. A part 50 is located within the vacuum chamber 30 and receives a coating during operation of the PVD system 10.

The cylindrical cathode 20 is constructed of two cathode segments 22, 24, a top cathode cap 26 and a bottom cathode cap 28. The cathode segments 22, 24 may be held in place via a thin tube 72 that is press-fit inside the cylindrical cathode 20. The top cathode cap 26 nests with a top nesting section 110 (described below with regards to FIG. 2) of the cathode segments 24 and the bottom cathode cap 28 nests with a bottom nesting section 120 (described below with regards to FIG. 2) of the bottom cathode segment 22. A magnet 70 is suspended within the cathode 20 and can be actuated between cathode segments 22, 24 using a vertically translatable shaft 74. The position of the magnet 30 controls the position of the cathodic arc according to known principles. The cylindrical cathode 20 is located in the center of the PVD system 10 via a plurality of cathode supports 60 and the actuation shaft 74.

Although the example PVD system 10, illustrated in FIG. 1, uses two cathode segments 22, 24, multiple additional segments can be used. Furthermore, the segmented post cathode 20 allows for cathode segments 22, 24 of varied axial lengths to be used.

A more detailed view of an example cathode segment 100 is illustrated in FIG. 2. The cathode segment 100 has a top nesting section 110, a bottom nesting section 120, and a side wall 140. In the illustrated example, the entire cathode segment 100 is constructed of the coating material and provides an evaporation source material surface for the cathode. The cathode segment 100 further includes an axial void 130 in which the thin tube 72 (illustrated in FIG. 1) can be inserted. The axial void 130 further provides for the magnet 70 to be moved between segments 100 during operation of the PVD system, and thereby allows the cathodic arc to be steered between the segments 100.

The top nesting section 110 of the cathode segment 100 is a radially inner ring portion 112 extending axially away from a body of the cathode post segment 100. The bottom nesting section 120 is an inner ring intrusion 122, extending axially inward toward the body of the cathode post segment 100. The inner ring extension portion 112 extends out to a same axial length as the intruding inner ring portion 122. The intruding inner ring inclusion portion 122 of the bottom nesting section 120 receives an inner ring extension section 112 of an adjacent post cathode segment 100, thereby “nesting” the two cylindrical post cathodes. The nesting function allows multiple post cathode segments 100 to be stacked together to form a single post cathode. When two segments 100 are stacked together, the arrangement appears as illustrated in FIG. 1. The top cathode cap 26 (illustrated in FIG. 1) and the bottom cathode cap 28 (illustrated in FIG. 1) each include corresponding nesting features, which provide for the caps 26, 28 to close the post cathode 20.

An alternative cathode segment 200 is illustrated in FIG. 3. As with the previous example, the cathode segment 200 includes a top nesting section 210, a bottom nesting section 220 and a solid side wall 240. Also included in the cathode segment 200 is an axial void 230 in which a thin tube can be press-fit, and through which a magnet may be actuated. In the example segment 200 of FIG. 3, the top and bottom nesting sections 210, 220 are a single planar cut and provide a contact surface 212 for abutting an adjacent cathode segment 200.

Since the cathode segments 200 use a simple planar cut for the nesting sections 210, 220, the top nesting section 210 and the bottom nesting section 220 are interchangeable. The interchangeability allows the cathode segment 200 to be reversible, with the top nesting section 210 of one cathode segment abutting an adjacent cathode segment 200 top nesting section 210.

A third alternative cathode segment 300 is illustrated in FIG. 4. The third cathode segment 300 includes a top nesting section 310, a bottom nesting section 320, a center void 330, and a side wall 340. The third cathode segment 300 differs from the first segment 100 and second segment 200 in that it uses a conical protrusion 310 and inclusion 320 as the nesting feature. In all other respects the three cathode segments 100, 200, 300 are the same.

In each of the cathode segments 100, 200, 300 of FIGS. 2, 3 and 4, a cylindrical post cathode segment 100, 200, 300 is illustrated. Alternate shapes, such as a rectangular post, could be used and still fall within the above disclosure. By using two or more post segments 22, 24, as is illustrated in FIG. 1, in a steered arc PVD system, a bi-layer coating (a coating having at least a first layer of a first coating and a second layer of a second coating) can be deposited on the part 50 in a single process. This functionality is achieved using at least one cathode segment constructed of the first coating material and another cathode segment constructed of the second coating material. Using a steered arc PVD system, such as the PVD system 10 illustrated in FIG. 1, the location of the cathodic arc can be controlled using the magnet 70. Control of the cathodic arc location controls which material is vaporized as a result of the arcing. By way of example, the arc may be controlled by maintaining the magnet 70 within a first cathode segment 22 for a first period of time and within a second cathode segment for a second period of time. Thus, material from the first segment 22 is deposited on the part 50 during a first period, and the material from the second segment 24 is deposited during a second period.

In a standard PVD system with random arcing, the cathodic arc can either favor or disfavor certain areas of the cathode due to variances in the cathode material. This favoring or disfavoring is exacerbated when multiple different materials are used to the point that one of the materials can have over 90% of the arcing. A steered arc system allows the arc position to be controlled, and thereby prevents the PVD arcing from improperly favoring one material over another.

In PVD systems using a traditional puck style cathode, it is possible for the random arcing to favor a certain point of the cathode. The favoring can result in wearing out the cathode at a select location, rather than evenly over the surface of the cathode. As such, traditional solid puck style cathode segments typically only get 20-40% material usage before they are no longer suitable as a cathode. By modifying the cathode to a hollow post cathode, such as the segmented cylindrical post cathode 20 illustrated in FIG. 1, and controlling the arc location, arc favoring is dramatically reduced, thereby providing for at least approximately 60-70% of the material to be used.

Although an example has been disclosed, a worker of ordinary skill in this art would recognize that certain modifications would come within the scope of the claims. For that reason, the following claims should be studied to determine their true scope and content.

What is claimed is:

1. A segmented post cathode comprising:
a plurality of post segments, each of said segments having an aligned central axis; and
each of said segments abutting at least one adjacent segment.

2. The segmented post cathode of claim 1, wherein said plurality of post segments comprises at least one post segment comprises a first coating material and at least one post segment comprises a second coating material.

3. The segmented post cathode of claim 2, wherein said segmented post cathode comprises at least a first segment constructed of a first material, and a second segment constructed of a second material.

4. The segmented post cathode of claim 1, wherein each of said post segments comprises a cylinder of evaporation source material, said cylinder having a center axis in an axial void; a top nesting section for connecting to another segment or a cathode cap; and a bottom nesting section for connecting to another segment or a cathode cap.

5. The segmented post cathode of claim 4, wherein a top joint of a first post segment comprises a nesting section capable of nesting with a bottom joint of a second post segment.

6. The segmented post cathode of claim 5, wherein said nesting section comprises a conical protrusion protruding axially away from said cylinder.

7. The segmented post cathode of claim 5, wherein said bottom joint comprises a conical intrusion protruding axially inward toward a center of said segment.

8. The segmented post cathode of claim 5, wherein said top nesting portion comprises a radially inner ring protruding axially away from a post segment body.

9. The segmented post cathode of claim 5, wherein said bottom nesting portion comprises a radially inner ring intruding axially into said post segment body.

10. The segmented post cathode of claim 4, wherein said segmented post cathode comprises an internal magnet capable of moving axially between at least a first segment and a second segment.

11. The segmented post cathode of claim 1, wherein each of said segments has a material use capacity of at least 50%.

12. The segmented post cathode of claim 11, wherein each of said segments has a material use capacity of approximately 60-70%.

13. The segmented post cathode of claim 4, wherein said nesting section comprises a simple planar surface.

14. A physical vapor deposition (PVD) system comprising:
a cathode comprising a plurality of hollow cathode segments, and a magnet suspended in a shared void within said cathode segments;
said magnet being connected to a shaft such that said magnet can be actuated axially between said segments.

15. The PVD system of claim 14, further comprising a vacuum chamber having an inner surface, and wherein said cathode is within said vacuum chamber.

16. The steered arc PVD system of claim 14, wherein each of said plurality of hollow cylindrical cathode segments comprises a top nesting section and a bottom nesting section.

17. The steered arc PVD system of claim 14, further comprising a thin tube in said void wherein said thin tube holds each of said segments in place.

18. The steered arc PVD system of claim 17, wherein said thin tube consists of non-ferrous and non-ferro-reactive materials.

19. A method for coating parts comprising the steps of:
placing at least one part within a physical vapor deposition (PVD) vacuum chamber;
providing a negative charge to a post cathode within said vacuum chamber, and a positive charge to an anode; and
controlling an arcing across a surface of said post cathode such that a coating material is vaporized and settles on a surface of said at least one part thereby coating it.

20. The method of claim 19, wherein said step of controlling an arcing across a surface of said post cathode further comprises the step of controlling a location of a magnet suspended within said post cathode.

21. The method of claim 20, wherein said step of controlling a location of a magnet suspended within said post cathode comprises moving said magnet axially between a first segment of said cathode when a first coating type is desired and a second segment of said cathode when a second coating type is desired.

22. The method of claim 19, further comprising the steps of:
selecting a number of coating materials desired for a part;
assembling a segmented post cathode from a plurality of segments comprising at least one segment constructed of each desired coating material; and
placing said assembled post cathode within said vacuum chamber.
